(19) United States
(12) Patent Application Publication
(10) Pub. No.: US 2022/0051907 A1
(43) Pub. Date: Feb. 17, 2022

(54) METHOD OF FABRICATING ELECTRONIC COMPONENT COOLING APPARATUS INCLUDING HEAT PIPES AND HEAT TRANSFER BLOCK

(71) Applicant: ZALMAN TECH CO., LTD., Anyang-si (KR)

(72) Inventor: Kuk Young YOON, Seoul (KR)

(73) Assignee: ZALMAN TECH CO., LTD., Anyang-si (KR)

(21) Appl. No.: 17/514,219

(22) Filed: Oct. 29, 2021

Related U.S. Application Data
(63) Continuation of application No. PCT/KR2019/017704, filed on Dec. 13, 2019.

(30) Foreign Application Priority Data
May 9, 2019 (KR) 10-2019-0054423

(51) Int. Cl. H01L 21/48; H01L 23/427

(52) U.S. Cl. CPC H01L 21/4882; H05K 7/20336; H01L 23/427

(57) ABSTRACT

A method of fabricating an electronic component cooling apparatus. In the electronic component cooling apparatus, a cooling tower includes a plurality of heat dissipation plates stacked on each other, and heat pipes extend through portions of the heat dissipation plates in the top-bottom direction. A heat transfer block includes a base having grooves receiving the heat pipes and a cover covering the heat pipes is located on a top surface of an electronic component. The method includes locating the base above the heat pipes and pressing the base to the heat pipes using a press so that the grooves receive the heat pipes, dropping Cu dust produced from the pressing, realigning an assembly of the base and the heat pipes so that the base is located below, and a fourth step of locating the cover above the assembly and pressing the cover to the assembly using the press.

### CROSS-REFERENCE TO RELATED APPLICATIONS

Pursuant to 35 USC 120 and 365(c), this application is a continuation of International Application No. PCT/KR2019/017704 filed on Dec. 13, 2019, which claims the benefit under 35 USC 119(a) and 365(b) of Korean Patent Application No. 10-2019-0054423, filed on May 9, 2019 in the Korean Intellectual Property Office, the entire disclosure of which is incorporated herein by reference for all purposes.

### BACKGROUND

### 1. Field

The present disclosure relates to a method of fabricating an electronic component cooling apparatus including heat pipes and a heat transfer block and, more particularly, to a method of fabricating an electronic component cooling apparatus, the method being configured to solve a problem in which heat dissipation efficiency is reduced by sintering occurring when a heat transfer block and heat pipes are coupled in an electronic component cooling apparatus having a cooling tower structure in which the heat pipes are inserted into the heat transfer block in contact with an electronic component.

### 2. Description

In general, a semiconductor integrated circuit (IC) refers to a small-scale circuit on which a plurality of circuit components, such as transistors, diodes, a variety of resistances, or capacitors, are provided on and coupled to a single substrate in a non-separable manner. Recently, semiconductor ICs have been widely used as components not only of computers and terminals but also of a variety of electronic devices, such as TVs, audio equipment, and electronic communication equipment, and are also fabricated at high-density integration rates.

Thus, the density of heat electrically generated by a variety of electronic components, such as a central processing unit (CPU), of computers is significantly increasing along with the integration rate of circuits. When the amount of heat generated by a variety of electronic components is increased in this manner, the temperature of semiconductors of ICs may also be increased. Thus, such increased heat may become a major reason for causing performance degradation in the system or failure, shortened lifespan, or the like of the equipment.

In order to cool heat generated by a variety of electronic components in this manner, a cooling method of using a heat dissipation fan disposed in a position adjacent to a heat dissipation plate is generally used. However, cooling efficiency obtained by only using the heat dissipation operation of the heat dissipation plate may be low. Thus, since the size of the heat dissipation plate may need to be relatively increased, a variety of problems, such as noise and insufficient cooling spaces, may occur. In order to overcome such problems, recently, a cooling technology using heat pipes has been used for cooling electronic components.

For example, Korean Registered Utility Model No. 20-0284564 (titled: HEAT ABSORBING BLOCK AND HEAT PIPE ASSEMBLY) relates to a cooling apparatus including heat pipes, i.e., an electronic component cooling apparatus configured to dissipate heat generated by a computer CPU.

This conventional technology discloses a heat absorbing block and heat pipe assembly including a heat absorbing block and heat pipes. The heat absorbing block has insertion holes extending through both ends and beads provided on surface portions adjacent to the insertion holes, along the insertion holes. The heat pipes are fitted into the insertion holes of the heat absorbing block and are pressed and fixed by the beads being pressed and deformed.

FIG. 1 is a perspective view illustrating a schematic structure of a known electronic component cooling apparatus including heat pipes.

In general, the electronic component cooling apparatus including heat pipes is provided in various types and structures. The cooling tower-type electronic component cooling apparatus is illustrated in FIG. 1 in order to promote an intuitive understanding of the conventional technology.

The cooling tower-type electronic component cooling apparatus illustrated in FIG. 1 has a structure including: a cooling tower 100 comprised of a plurality of heat dissipation plates 110 and 120 stacked on each other at predetermined distances in a height direction; heat pipes 140 extending in the height direction while penetrating through portions of the heat dissipation plates 110 and 120; and a heat transfer block 150 holding the heat pipes 140 therein, with an electronic component being located on the bottom surface of the heat transfer block 150.

That is, the heat transfer block 150 first absorbs heat from the electronic component and then conducts the absorbed heat to the heat pipes 140, and the heat dissipation plates 110 and 120 of the cooling tower 100 connected to the heat pipes 140 ultimately dissipate the heat.

According to this structure (including the above-described conventional technology), the heat pipes 140 serve as framework conducting heat from the heat transfer block 150 to the cooling tower 100 and supporting the cooling tower 100. In particular, as a structure of coupling the heat pipes 140 to the heat transfer block 150, it is general to form holes in the heat transfer block 150 and to insert and fit the heat pipes 140 into the holes.

In this case, the heat transfer block 150 includes a first plate located below the heat pipes 140 and a second plate located above the heat pipes 140. Each of the plates has grooves corresponding to the half shape (or possibly other shapes) of the heat pipes 140. After the heat pipes 140 are coupled to the first plate, the heat pipes 140 are covered with the second plate. Since the heat pipes 140 have a cylindrical structure, first, the heat pipes 140 are fixed, and then, the first plate is moved toward the heat pipes 140 and pressed against the heat pipes 140.

Specifically, according to a known process, in a position in which the heat pipes 140 are located above and the first plate is located below, the second plate is moved toward the heat pipes 140, i.e., in the bottom to top direction, and pressed against the heat pipes 140. Here, when the heat pipes 140 generally made of copper (Cu) are pressed, in particular, thermally pressed, against the first and second plates, fine dust may be produced by the heat pipes 140.

However, according to the above-described process, the produced dust is trapped between the heat pipes 140 and the first plate and is sintered by heat provided after or simultaneously with the pressing. When the heat transfer block 150 and the heat pipes 140 are integrated in this manner, the objective of obtaining a heat dissipation effect due to the difference in the thermal conductivity between the heat transfer block 150 and the heat pipes 140 made of different materials may be reduced. Consequently, heat dissipation performance may be inferior to the intended performance, which is problematic.

Therefore, there is demand for the development of a method of fabricating an electronic component cooling apparatus, the method being configured to provide a novel and improved combination of heat pipes and a heat transfer block by overcoming the above-described problems. The method may reliably prevent sintering while separating heat pipe dust produced during pressing.

### BRIEF SUMMARY

The present disclosure has been devised to overcome the above-described problems occurring the related art, and is intended to provide a method of fabricating an electronic component cooling apparatus, the method including a process of coupling and fixing heat pipes and a heat transfer block by, for example, a reverse pressing method in order to prevent a heat dissipation function from being degraded by sintering caused by dust produced during the coupling of the heat pipes and the heat transfer block.

Another objective of the present disclosure is to efficiently prevent sintering by proposing various structures of groove to which the heat pipes are coupled.

Another objective of the present disclosure is to prevent dust from unnecessarily moving by applying an adsorbent to the surface of grooves to which the heat pipes are coupled.

Another objective of the present disclosure is to improve adsorption performance by providing the adsorbent with grain skin and proposing a characteristic process for the grain skin of the adsorbent.

In order to realize at least one of the above-described objectives, provided is a method of fabricating an electronic component cooling apparatus including a cooling tower included of a plurality of heat dissipation plates stacked on each other with predetermined gaps in a top-bottom direction and heat pipes extending through portions of the heat dissipation plates in the top-bottom direction, wherein a heat transfer block including a base having grooves receiving the heat pipes and a cover covering the heat pipes is located on a top surface of an electronic component. The method may include: a first step of locating the base above the heat pipes and pressing the base to the heat pipes using a press so that the grooves receive the heat pipes; a second step of dropping Cu dust produced from the pressing; a third step of realigning an assembly of the base and the heat pipes so that the base is located below; and a fourth step of locating the cover above the assembly and pressing the cover to the assembly using the press.

Each of the heat pipes may have a circular terminal shape. Each of the grooves may have a semielliptical terminal shape in which a major axis thereof longer than each radius of the heat pipes extends in a direction in which a corresponding one of the heat pipes is inserted into the groove, such that an air gaps is defined between the heat pipe and the groove in the pressing of the first step.

The terminal shape of the groove may include: chamfers obtained by chamfering entrance-side corners of the groove to be round; semielliptical extensions extending in a semielliptical shape, with the major axis longer than a radius of the heat pipe extending in the direction in which the heat pipe is inserted into the groove; and a round protrusion protruding from a central portion of a bottom surface of the groove in a direction of the heat pipe.

The method of fabricating an electronic component cooling apparatus including heat pipes and a heat transfer block according to the present disclosure has the following effects.

1) It is possible to reliably maintain heat dissipation performance by minimizing sintering of remaining dust, which is produced from the heat pipes, using the reverse pressing method.

2) it is possible to more efficiently prevent sintering using various groove structures and resultant unique coupling relationships of the grooves and the heat pipes.

3) It is possible to prevent unnecessary movement of dust using the adsorbent capable of adsorb dust.

4) It is possible to enhance adsorption performance using a specific component of the adsorbent.

### DESCRIPTION OF DRAWINGS

FIG. 1 is a perspective view illustrating a schematic structure of a known electronic component cooling apparatus including heat pipes;

FIG. 2 is a conceptual view illustrating a process of coupling heat pipes and a heat transfer block according to the present disclosure;

FIG. 3 is a cross-sectional view illustrating a modified embodiment of the groove;

FIG. 4 is a cross-sectional view illustrating a first additional embodiment of the groove according to FIG. 2; and

FIG. 5 is a partially-enlarged cross-sectional view illustrating a second additional embodiment of the groove according to FIG. 2.

### DETAILED DESCRIPTION

Hereinafter, exemplary embodiments of the present disclosure will be described in detail with reference to the accompanying drawings. It should be understood that the accompanying drawings may not be drawn to scale, and the same or like reference numerals may be used to refer to the same or like elements throughout the drawings.

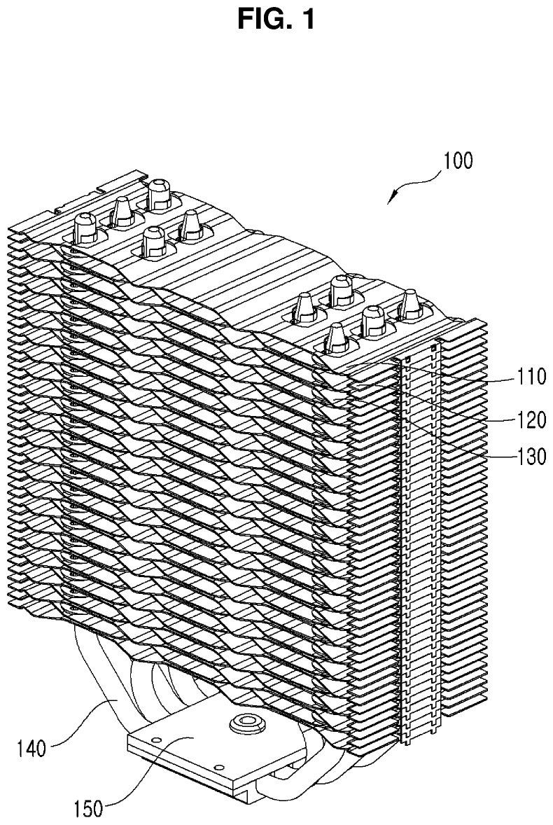

First, a cooling apparatus according to the present disclosure has a structure similar to that of the electronic component cooling apparatus illustrated in FIG. 1. Specifically, the cooling apparatus has a basic structure comprised of a cooling tower 100 in which a plurality of heat dissipation plates 110 and 120 are stacked on each other with predetermined gaps in the top-bottom direction and heat pipes 140 extending through portions of the heat dissipation plates 110 and 120 in the top-bottom direction. Here, a heat transfer block 150 including a base 151 having grooves 200 receiving the heat pipes 140 and a cover 152 covering the heat pipes 140 is located on the top surface of the electronic component.

On the basis of this structure, a fabrication method according to the present disclosure, more particularly, a coupling process of the heat pipes 140 and the heat transfer block 150, will be described hereinafter.

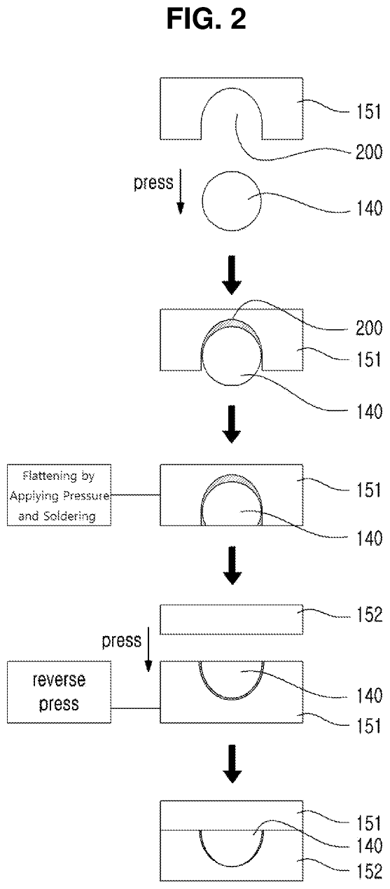

FIG. 2 is a conceptual view illustrating the process of coupling the heat pipes and the heat transfer block according to the present disclosure.

Referring to FIG. 2, it may be seen that the method of fabricating an electronic component cooling apparatus including the process of coupling the heat pipes and the heat transfer block according to the present disclosure is generally divided into four steps. Respective steps will be described in detail as follows.

1. Step of Pressing Base Including Heat Pipes and Grooves by Reverse Pressing

First, the heat pipes 140 are fixedly arranged on a shelf or another worktable so as not to be movable. Here, vises may be provided on the worktable to fix the lower portions (or other portions depending on the work situation) of the heat pipes. To ensure the efficiency of work, the heat pipes 140 may have a structure that has not yet been coupled to the cooling tower 100 or any partial structure except for the structure coupled to the heat dissipation plates 110 and 120.

In addition, the heat pipes 140 may have the shape of a rod having various three-dimensional (3D) structures. The heat pipes 140 may have a cylindrical shape, i.e., a circular terminal shape, in order to ensure reliable coupling to the heat transfer block and to match various 3D structures of the base as will be described below. However, in the basic embodiment of the present disclosure, the heat pipes are not necessarily limited to cylindrical heat pipes. In addition, the following process will be described on the assumption that the heat pipes 140 is made of a commonly used material, i.e., copper (Cu), although the heat pipes 140 may be made of a variety of heat conductive materials.

Afterwards, the base 151 is aligned above the heat pipes 140 such that the grooves 200 face the heat pipes 140.

The grooves 200 are shaped as recessed grooves for receiving the heat pipes 140 and serve to receive the heat pipes 140. The grooves 200 may have a variety of shapes that may provide spaces configured to receive the heat pipes 140. In order to minimize the gaps formed when the heat pipes 140 are inserted into the grooves 200, the grooves may have 3D shapes having predetermined curvatures depending on the shapes of the heat pipes 140, thereby minimizing the gaps.

Here, the cover 152 is comprised of a flat plate with no grooves to serve to cover the grooves 200 into which the heat pipes 140 are inserted. Alternatively, the grooves 200 may be configured such that each volume thereof is smaller than that for receiving the entire volume of the corresponding heat pipe 140, thereby leaving portions of the heat pipes 140 to exposed from the grooves 200, and the cover 152 may have grooves configured to surround and receive the exposed portions of the heat pipes 140.

The following structure will be described on the assumption that the cover 152 is a flat plate.

After a press (or a press machine) has supported the base 151 in a position above the heat pipes 140, the press may move the base 151 downward, i.e., toward the heat pipes 140 so that some portions of the heat pipes 140 are inserted into the grooves 200 and then convert the exposed portions of the heat pipes 140, which have not been received in the grooves 200, into a flat shape by applying a predetermined amount of pressure to the heat pipes 140, so that the cover 152 may be coupled to the resultant structure as will be described below. In other words, the volume of each of the grooves 200 is not necessarily configured to receive the entire volume of the corresponding heat pipe 140. The remaining portions of the heat pipes 140, which are not received in the grooves 200, may be converted to be flat, under the pressure applied by the press. In this pressing process, heat may be applied.

In a known process, the heat pipes 140 are inserted into the grooves 200 in a position in which the grooves 200 are aligned such that open areas thereof face upward. In contrast, the present disclosure provides a process of moving the base 151 located above the heat pipes 140 toward the heat pipes 140 and fitting the grooves 200 around the heat pipes 140 by applying pressure while maintaining the heat pipes 140 in a fixed position. This method will be referred to as reverse pressing in the present disclosure. In this process, the press may be comprised not only of a single press that applies pressure in the top-to-bottom direction but also of two presses. When the two presses are provided, for conversion of the heat pipes 140 into a flat shape, a process of pressing the remaining portions (i.e., mainly bottom portions) of the heat pipes 140 not received in the grooves 200 by upwardly moving a support structure on which the heat pipes 140 are supported may be added.

That is, in the known process, Cu dust produced during the pressing remains in the grooves 200 and is sintered by heat, thereby degrading the heat dissipation effect, which is problematic. In contrast, the present disclosure may be characterized in that the open areas are formed in the grooves 200 to be open in the direction of gravity, thereby allowing Cu dust produced from the heat pipes 140 during the pressing to naturally drop through the open areas.

2. Step of Dropping Dust Produced from Heat Pipes During Pressing

According to the above-described first step, the open areas of the grooves 200 are open in the direction of gravity such that dust (i.e., Cu dust) produced from the heat pipes 140 may freely fall. Dust remaining around the coupling portions of an assembly of the grooves 200 and the heat pipes 140 (referred to as an “assembly” herein) may be swept, or may be allowed to freely fall by vibrating the assembly for 10 to 30 seconds or leaving the assembly.

3. Step of Realigning Assembly of Base and Heat Pipes

The assembly of the base 151 and the heat pipes 140 is realigned by inverting the assembly using a robot arm or another device so that the base 151 is located below and the heat pipes 140 are located above, and a worktable is also fixed so as not to move.

In this case, the top area of the assembly with respect to the reference line is not coupled to the base but is in a position in which the heat pipes are exposed. The cover 152 is coupled to the exposed portions of the heat pipes 140 as will be described below.

4. Step of Pressing Cover Against Assembly

In the position in which the cover 152 is located above the assembly, the cover 152 is pressed to the assembly by applying pressure using the press. In this manner, the process of coupling the heat pipes 140 and the heat transfer block 150 is completed. In this process, the thermal pressing may also be used, thereby reliably coupling the contact portions of the base 151 and the cover 152.

As described above, the cover 152 has a base structure having a flat shape. The cover 152 may also have partially recessed grooves depending on the shape and volume of the heat pipes and the grooves.

The cover 152 may have the same area and thickness as the base or a different area and thickness from the base. In addition, after the cover 152 having a greater area than the base 151 is coupled to the base 151, the cover 152 may be fixedly coupled to a substrate or a circuit board on which the electronic component is mounted by inserting fasteners into fastening holes provided in both sides of the cover 152. In addition, each of the cover 152 and the base 151 may also have fastening holes, such that the coupling of the cover 152 and the base 151 may be completed by finally coupling fasteners into the fastening holes.

In addition, when the gaps are formed due to the 3D structure of the grooves 200 and the heat pipes 140, an operation of soldering a known filler (e.g., a paste) capable to filling the gaps to prevent sintering may be provided before the cover coupling step.

Accordingly, provided is the feature capable of overcoming the problem in that the heat dissipation function is degraded due to the sintering or remaining of dust produced during the coupling of the heat pipes 140 to the heat transfer block 150 comprised of two pieces, i.e., the base 151 and the cover 152.

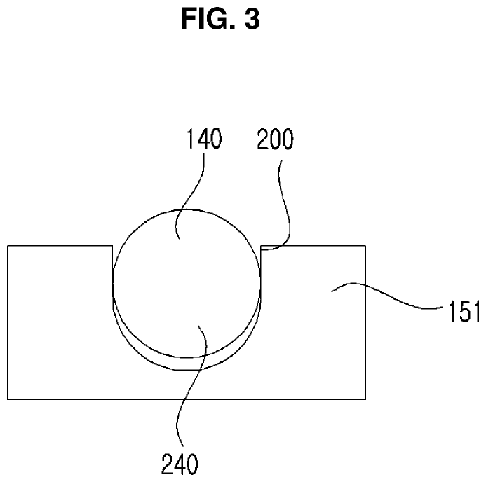

FIG. 3 is a cross-sectional view illustrating a modified embodiment of the groove.

As described above, the heat pipes 140 may have a variety of 3D shapes. The embodiment illustrated in FIG. 3 proposes a structure in which the heat pipes 140 has a circular terminal shape.

Here, the grooves 200 does not have a semicircular terminal shape but has a semielliptical terminal shape (or a shape in which a portion of an ellipse is cut, rather than being a complete semielliptical terminal shape) in which the major axis thereof longer than the radius of the heat pipes 140 extend in the insertion direction (i.e., the height direction). According to this structure, spaces are left the grooves 200 after the heat pipes 140 are coupled to the grooves 200. Specifically, the heat pipes 140 are tightly coupled to the grooves 200 in the direction of the minor axis, but the gaps having a terminal shape similar to the half-moon or the crescent may be formed between the bottom ends of the heat pipes 140 and the matching surfaces of the grooves 200.

In the pressing of the first step, the pressure may be adjusted to maintain the gaps, instead of filling the gaps by forcibly pressing the heat pipes 140 toward the grooves 200. In the present disclosure, these gaps are referred to as air gaps 240 in which air is contained.

The air gaps 240 may form air-containing spaces between the heat pipes 140 and the base 151 to serve to buffer or reduce the sintering during the thermal pressing caused by a small amount of Cu dust remaining in the grooves 200 or a minute amount of Cu dust adhering to the surface of the grooves 200.

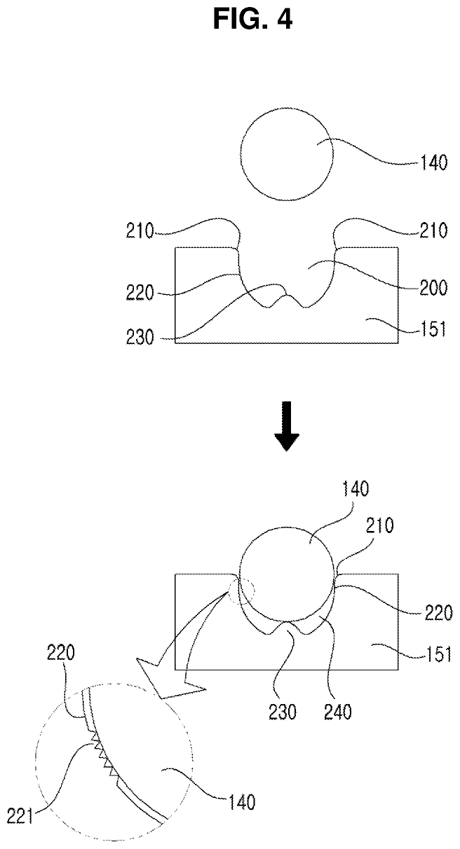

FIG. 4 is a cross-sectional view illustrating a first additional embodiment of the groove according to FIG. 2.

The embodiment illustrated in FIG. 4 includes additional components added to the embodiment illustrated in FIG. 2. As illustrated in FIG. 2, chamfers 210, semielliptical extensions 220, and a round protrusion 230 are additionally provided on the semielliptical terminal shape of the grooves 200 (or, possibly, a shape in which a portion of the ellipse is cut, rather than being a complete semielliptical terminal shape, as described above) with the major axis extending in the top-bottom direction.

Specifically, the chamfers 210 are portions formed by chamfering entrance-side (or opening-side) corners of each of the grooves 200 to be round, and the semielliptical extensions 220 are portions formed by extending the grooves 200 to have the above-described semielliptical shape. Here, the chamfers 210 may be formed by enlarging the opening-side entrance portion of each of the grooves 200 in order to prevent Cu dust from being unnecessarily produced from the heat pipes 140 caught by or colliding with the entrance-side corners of the groove 200 when the heat pipes 140 are introduced into the grooves 200.

The semielliptical extensions 220 are the portions extending to the vicinity of the central portion of the bottom surface of the groove 200 to have the above-described semielliptical shape (i.e., the semielliptical shape with the major axis extending in the top-bottom direction). In addition, a round portion may protrude from the central portion of the bottom surface of the groove 200 in the direction of the heat pipes 140. This round portion is referred to as the round protrusion 230.

The round protrusion 230 may serve to prevent the air gap 240 from being excessively wide, allow the bottom surface of the groove to be in contact with the bottom of the heat pipe, and leave a minimum space in which remaining Cu dust is not fused or sintered, thereby enabling the function illustrated with reference to FIG. 2 to be maintained.

Furthermore, wrinkled portions 221 each comprised of a plurality of ridges and valleys extending in the insertion direction (i.e., the height direction) of the heat pipe 140 may be additionally provided on partial areas of the semielliptical extensions 220, e.g., upper portions substantially adjacent to the central portion with respect to the height.

The wrinkled portions 221 provide spaces in which a portion of dust remaining on both side portions of the heat pipes 140 may be accommodated, thereby serving to prevent sintering on the side portions of the heat pipes 140. Here, when the differences between the ridges and valleys are unnecessarily large, close coupling between the heat pipes 140 and the base 151 may be obstructed. In order to prevent this problem, the differences between the ridges and valleys may range approximately from 0.5 to 1.5 mm.

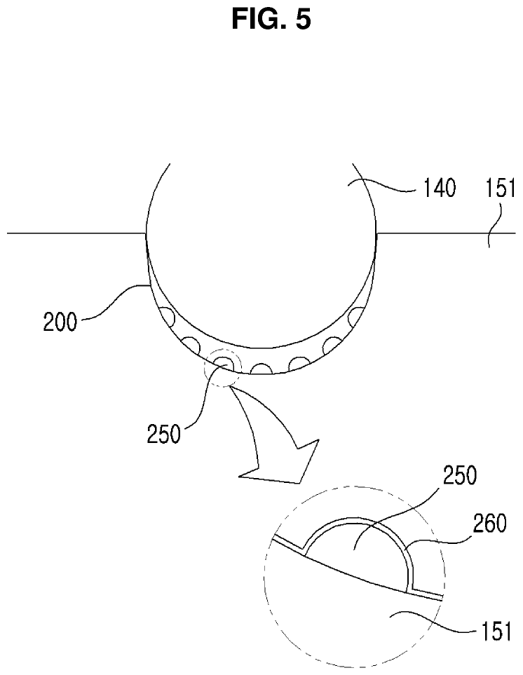

FIG. 5 is a partially-enlarged cross-sectional view illustrating a second additional embodiment of the groove according to FIG. 2.

The embodiment illustrated in FIG. 5 also includes additional components added to the embodiment illustrated in FIG. 2. As illustrated in the figure, a plurality of protrusions 250 protrude from the surface of a portion of the groove 200 in which the air gap 240 is formed.

The protrusions 250 are intended to occupy unnecessary spaces of the air gap 240 when the above-described round protrusion 230 has a single size having a relatively large volume. In other words, the plurality of protrusions 250 are intended to ensure the contact between the bottom surface of the groove 200 and the heat pipe 140 and form a plurality of spaces smaller than the space defined by the round protrusion 230, wherein the plurality of spaces are at predetermined distances from each other for stabilization of Cu dust.

Furthermore, an adsorbent 260 containing grain skin is applied on the surface of the groove 200 having the protrusions 250.

The adsorbent 260 adsorbs Cu dust to prevent the Cu dust from moving in the spaces between the protrusions 250 during the above-described process. In particular, the adsorbent 260 according to the present disclosure may contain the environmental friendly grain skin having excellent adsorption ability and adsorb Cu powder through pores formed in the grain skin.

A step of producing the adsorbent 260 having the above-described characteristics may specifically include a carbonization step, an immersion-stirring step, a heating and drying step, a first substance producing step, an activation step, a second substance producing step, and an adsorbent completing step.

First, the carbonization step is a process of carbonizing the grain skin by heating the grain skin to a temperature of from 600 to 800° C. at a temperature rise rate of 5° C./min in a nitrogen (N₂) stream of 100 mL/min, maintaining the temperature for 1 to 5 hours, and cooling the grain skin at room temperature.

Through this process, pores are formed in the surface of the grain skin. Due to the silicon of the grain skin, a composition similar to fumed silica may be obtained after calcination. The grain skin carbonized in this manner is a calcined substance having minute pores. The grain skin has very high activity due to a large specific surface area of from 40,000 to 60,000 m²/kg, and thus, can adsorb a large amount of gas. In addition, due to high activity, the strength and durability of the adsorbent 260 produced from the grain skin may be increased.

Afterwards, the immersion-stirring step is a process of immersing the carbonized grain skin into a sodium hydroxide (NaOH) solution and then heating and stirring the resultant mixture for 1 to 5 hours.

Here, the sodium hydroxide solution is an agent for activating the carbonized grain skin. The term “activation” used herein means improving adsorption performance of a porous substance by further increasing the surface area of the porous substance. By the immersion of the carbonized grain skin into the sodium hydroxide solution, the activated grain skin may be obtained. Here, the sodium hydroxide solution may contain sodium hydroxide of 5 to 10 mol.

Subsequently, the heating-drying step is a process of immersing the immersed grain skin into water, heating the resultant mixture at a temperature of from 90 to 110° C., cleaning the grain skin with water 1 to 5 times, and then drying the grain skin. By heating the water-immersed grain skin at the above-temperature condition, residual sodium hydroxide may be removed. By performing vacuum drying at a temperature of from 80 to 130° C. (more particularly, from 110 to 120° C.), water used in the cleaning may be evaporated, thereby finally obtaining the carbonized grain skin.

Afterwards, the first substance producing step is a process of producing the first substance by mixing, by weight, 1 to 20% of the grain skin having passed through the heating-drying step, 50 to 80% of potassium hydroxide (KOH), and 10 to 40% of water, heating and stirring the resultant mixture at a temperature of from 50 to 70° C., and drying the resultant mixture at room temperature.

Here, the carbonization means burning a substance. The carbonized substance may be carbon. In the present disclosure, it is possible to carbonize rice husks that may cause soil pollution and adsorb toxic gas produced during semiconductor fabrication processes using the rice husks. It is also possible to prevent soil pollution that would otherwise be caused when an adsorbent is discarded. Rice husks produce smaller amounts of sulfur oxides and nitrogen oxides during carbonization, compared to the carbonization of other substances. Accordingly, an air pollution preventing effect may also be provided.

Afterwards, the activation step is a process of activating the first substance by inputting the first substance into a ceramic boat in a nitrogen current, raising the temperature to 700 to 900° C. at a temperature rise rate of 10° C./min, maintaining the temperature for 2 to 5 hours, and cooling the first substance at room temperature.

Since the ceramic boat is not influenced by acid, alkali, or an organic solvent due to chemical resistance and abrasive resistance thereof, the ceramic boat may be regarded to be appropriate to immerse an active material into a potassium hydroxide solution. In addition, the ceramic boat may be used at a temperature of 1600° C. or higher. Thus, the ceramic boat may sufficiently immerse the carbonized grain skin into the potassium hydroxide solution to be activated without being damaged at a high temperature condition.

Subsequently, the second substance producing step produces the second substance by immersing the activated first substance into water and heating the first substance at a temperature of 80 to 100° C. This step serves to easily remove the remaining potassium hydroxide from the high-temperature first substance by heating the activated first substance at a temperature of 80 to 100° C.

Finally, the adsorbent completing step completes the adsorbent by filtering the second substance, cleaning the second substance with water 1 to 5 times, and drying the second substance at a temperature of 90 to 120° C. for 12 to 30 hours. This step may be referred to as a process of maximizing the adsorption performance of the adsorbent by further increasing the surface area of the grain skin by producing the activated grain skin by cleaning and then drying the second substance in the above-describe temperature conditions.

When the adsorbent 260 produced in this manner is applied on the surface of the grooves 200 having the protrusions 250, superior adsorption performance for dust, i.e., Cu dust, can be performed, thereby more efficiently prevent dust from being sintered.

As set forth above, the configuration and operation of the method of fabricating an electronic component cooling apparatus including heat pipes and a heat transfer block according to the present disclosure have been expressed in the description and illustrated in the drawings, merely by way of example. The scope of the present disclosure is not limited to the description and drawings, and may be variously changed and modified without departing from the technical idea of the present disclosure.

### DESCRIPTION OF REFERENCE NUMERALS

100: cooling tower
110, 120: heat dissipation plate
130: air channel
140: heat pipe
150: heat transfer block
151: base
152: cover
200: groove
210: chamfer
220: semielliptical extension
221: wrinkled portion
230: round protrusion
240: air gap
250: protrusion
260: adsorbent

What is claimed is:

1. A method of fabricating an electronic component cooling apparatus comprising a cooling tower comprised of a plurality of heat dissipation plates stacked on each other with predetermined gaps in a top-bottom direction and heat pipes extending through portions of the heat dissipation plates in the top-bottom direction, wherein a heat transfer block comprising a base having grooves receiving the heat pipes and a cover covering the heat pipes is located on a top surface of an electronic component, the method comprising:
a first step of locating the base above the heat pipes and pressing the base to the heat pipes using a press so that the grooves receive the heat pipes;
a second step of dropping Cu dust produced from the pressing;
a third step of realigning an assembly of the base and the heat pipes so that the base is located below; and
a fourth step of locating the cover above the assembly and pressing the cover to the assembly using the press.

2. The method according to claim 1, wherein each of the heat pipes has a circular terminal shape, and
each of the grooves has a semielliptical terminal shape in which a major axis thereof longer than each radius of the heat pipes extends in a direction in which a corresponding one of the heat pipes is inserted into the groove, such that an air gaps is defined between the heat pipe and the groove in the pressing of the first step.

3. The method according to claim 2, wherein the terminal shape of the groove comprises:
chamfers obtained by chamfering entrance-side corners of the groove to be round;
semielliptical extensions extending in a semielliptical shape, with the major axis longer than a radius of the heat pipe extending in the direction in which the heat pipe is inserted into the groove; and
a round protrusion protruding from a central portion of a bottom surface of the groove in a direction of the heat pipe.

4. The method according to claim 3, wherein a wrinkled portion comprising a plurality of ridges and valleys extending in the direction in which the heat pipe is inserted into the groove is provided on a predetermined area of the semielliptical extension.

5. The method according to claim 2, wherein a plurality of protrusions protrude from a surface of a portion of the groove in which the air gap is defined.

6. The method according to claim 5, wherein an adsorbent containing grain skin is applied on the surface of the groove on which the protrusions are provided.

7. The method according to claim 6, wherein the adsorbent is produced by:
a carbonization step of carbonizing the grain skin by heating the grain skin to a temperature of 600 to 800° C. at a temperature rise rate of 5° C./min in a nitrogen stream of 100 mL/min, maintaining the temperature for 1 to 5 hours, and cooling the grain skin at room temperature;
an immersion-stirring step of immersing the carbonized grain skin into a sodium hydroxide (NaOH) solution and then heating and stirring the resultant mixture for 1 to 5 hours;
a heating-drying step of immersing the immersed grain skin into water, heating the resultant mixture at a temperature of from 90 to 110° C., cleaning the grain skin with water 1 to 5 times, and then drying the grain skin;
a first substance producing step of producing a first substance by mixing, by weight, 1 to 20% of the grain skin having passed through the heating-drying step, 50 to 80% of potassium hydroxide (KOH), and 10 to 40% of water, heating and stirring the resultant mixture at a temperature of from 50 to 70° C., and drying the resultant mixture at room temperature;
an activation step of activating the first substance by inputting the first substance into a ceramic boat in a nitrogen current, raising a temperature to 700 to 900° C. at a temperature rise rate of 10° C./min, maintaining the temperature for 2 to 5 hours, and cooling the first substance at room temperature;
a second substance producing step of producing a second substance by immersing the activated first substance into water and heating the first substance at a temperature of 80 to 100° C.; and
an adsorbent completing step of completing the adsorbent by filtering the second substance, cleaning the second substance with water 1 to 5 times, and drying the second substance at a temperature of 90 to 120° C. for 12 to 30 hours.
